(19) United States
(12) Patent Application Publication
(10) Pub. No.: US 2026/0256059 A1
(43) Pub. Date: Sep. 3, 2026

(54) Safety Device for Monitoring a Treatment Device for Plants

(71) Applicant: crop.zone GmbH, Aachen (DE)

(72) Inventors: Fabian Effey, Aachen (DE); Ronny Galonska, Aachen (DE); Peter Frings, Aachen (DE); Johannes Schollmeyer, Aachen (DE); Manfred Rader, Aachen (DE); Achim Andres, Aachen (DE); Dirk Vandenhirtz, Aachen (DE)

(21) Appl. No.: 18/872,818

(22) PCT Filed: May 12, 2023
(86) PCT No.: PCT/EP2023/062817

§ 371 Date: Dec. 7, 2024

(30) Foreign Application Priority Data
Jun. 10, 2022 (DE) 10 2022 114 635.9

(51) Int. Cl. A01G 7/04; A01M 21/04; G01R 17/02

(52) U.S. Cl. CPC A01G 7/04; A01M 21/046; G01R 17/02

(57) ABSTRACT

The invention relates to a method for treating plants, having the steps: detecting a sensor signal indicative of a rotation of a grounding disk by means of a wheel rotational speed sensor of a safety device in order to deduce that the grounding disk is in contact with the ground, starting up a treatment device by way of the safety device if a rotation of the grounding disk and/or no electrical current flowing through the grounding disk have/has been detected.

### CROSS REFERENCE TO RELATED APPLICATION

This application is a U.S. National Stage entry under 35 U.S.C. § 371 based on International Application No. PCT/EP 2023/062817, filed on May 12, 2023, which was published under PCT Article 21(2) and which claims priority from German Application No. 102022114635. 9, filed on Jun. 10, 2022. The disclosure of each of the foregoing documents is incorporated herein by reference.

### TECHNICAL FIELD

The invention relates to a method, a computer program product and a safety device for monitoring a treatment device for treating plants, in particular for desiccating field crops, for green manure control or for weed control. Furthermore, the invention relates to a carrier vehicle having such a safety device and a kit containing components of such a safety device.

### BACKGROUND

Desiccation (dry-down) is a practice in agriculture in which herbicides are applied immediately before harvest. It facilitates harvesting and promotes the ripening of arable crops. This practice mimics the natural desiccation process of wilting of cultivated plants when the fruit ripens, in which the green parts of the plant above ground turn brown. A welcome side effect is the simultaneous killing of weeds, the still green plant parts of which would otherwise be harvested, for example, with cereals and would increase the moisture content of

Field crops or arable crops are cultivated plants that are grown in fields. Field crops include, for example, cereals, root crops and legumes, oil crops or plants for green harvesting, which are used as animal feed or, like silage maize, for energy production.

Green manuring is the targeted cultivation of plants for soil improvement in arable farming, fruit growing, viticulture and horticulture. Unlike crops, the plants are usually not harvested, but mulched or plowed under.

If electrical current flows through plant parts, they are damaged as a function of electrical current strength, electric voltage, current type (direct current, alternating current, frequency, degree of smoothing or residual ripple, etc.). A comprehensive and uniform theory of the effect has not been present until now. It can be safely assumed that in particular the conductive bundles for transporting liquid in the plant, as the parts with the lowest electric resistance, are damaged in such a manner that they become non-functional and the plant subsequently dies and withers, depending on the degree of damage and the weather conditions.

The use of direct electrical current for treating plants is known, for example, from U.S. Pat. No. 2,007,383 and WO 2019/052591 A1, while the use of direct electrical current or alternating electrical current is known, for example, from WO 2018/095450 A1 or WO 2018/050142 A1.

Traditionally, two metallic applicators are used when applying electrical current to plants, at least to keep the electric resistance at the contact point as low as possible.

Such applicators are also referred to as long applicators (long range applicators, also tongue applicators or LRBs (“long range blade”). Such applicators have a distance of 0.8 to 1 m, for example. However, short applicators (SRA, short range blade) can also be used, with a distance in the range of between 0.1 m and 0.5 m.

Furthermore, in some cases the circuit is closed not by a second contact on plants with the opposite pole, but by electrodes cutting into the soil.

The use of high electric voltages requires wide clearances and barriers for reasons of occupational safety (in particular when metallic conductors are present in the work region, such as in a vineyard or in urban applications). Such devices are correspondingly expensive due to elaborate insulation and disadvantageously large due to increased clearance requirements for creepage distances and clearances. The technical and economic applicability is therefore low.

U.S. Pat. No. 4,338,744 A1 discloses measures to increase safety during operation of a device for the electric treatment of plants.

There is therefore a need to identify ways in which improvements in occupational safety can be made here.

### SUMMARY

The object of the invention is achieved by a method comprising the steps of: detecting a sensor signal indicative of a rotation of a grounding disk by means of a wheel rotational speed sensor of a safety device in order to deduce that the grounding disk is in contact with the ground, starting up a treatment device by way of the safety device if a rotation of the grounding disk and/or no electrical current flowing through the grounding disk have/has been detected.

The treatment device is therefore only activated and thus electric voltages that constitute a source of danger are only applied if the grounding disk rotates and/or no electrical current flowing through the grounding disk has been detected. It is assumed that the grounding disk only rotates when the grounding disk is in contact with the ground and the carrier vehicle is moving forward in the direction of travel. The fact that the grounding disk is in contact with the ground ensures reliable detection of a flowing electrical current.

If a carrier vehicle is moving forward in the direction of travel, it can be assumed that, for example, no person is in the region of the applicators or touching them. The fact that the safety device only allows the treatment device to be started up if no electrical current flowing through the grounding disk has been detected ensures that no treatment device that is already damaged is started up. Such a start-up would otherwise result in a residual current, for example due to an electric insulation of a component of the treatment device being damaged in the meantime.

This is a particularly simple way of significantly reducing the risk of injury.

According to one embodiment, the following steps are performed: detecting an electrical current flowing through the grounding disk by means of the safety device, and

deactivating the treatment device by way of the safety device if a flowing electrical current has been detected.

This means that a residual electrical current is detected which, for example, occurs after start-up as a result of the electric insulation of a component of the treatment device being damaged in the meantime and which now partially flows through the grounding disk. This is a particularly simple way of significantly reducing the risk of injury once again.

According to a further embodiment, the sensor signal indicative of a rotation of the grounding disk is detected by means of the safety device for a predetermined minimum time period, and the treatment device is started up by way of the safety device if the sensor signal has been detected continuously for the minimum time period. In other words, start-up only occurs when a predetermined minimum frequency is reached. The treatment device is therefore only activated and thus dangerous electric voltages are only applied after the minimum time period has elapsed. This reduces the risk of injury, in particular when the carrier vehicle starts moving. This also ensures that start-up cannot take place when the carrier vehicle is stationary, i.e., not moving.

According to a further embodiment, the following further steps are performed:

determining an electrical current strength of the detected electrical current by way of the safety device,

comparing the determined electrical current strength to a threshold value by way of the safety device, and deactivating the treatment device by way of the safety device if the determined electrical current strength of the flowing electrical current is greater than the threshold value.

This ensures that the treatment device is only deactivated if the minimum current strength permitted by the guidelines is exceeded. This means that harmless electrical current strengths cannot result in deactivation of the treatment device. This ensures continuous operation of the treatment device without unnecessary interruptions.

The invention further relates to a computer program product, a safety device for monitoring a treatment device for treating plants, in particular for desiccating field crops or for green manure control, a carrier vehicle having an associated safety device of this type and a kit containing components of such a safety device.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 is a schematic side view of an embodiment of a carrier vehicle having a treatment device for treating plants and having a safety device.

FIG. 2 is a schematic representation of a plan view of the carrier vehicle shown in FIG. 1.

FIG. 3 is a schematic representation of mechanical components of the safety device.

FIG. 4 is a schematic representation of further details of FIG. 3.

FIG. 5 is a schematic representation of further details of FIG. 3.

FIG. 6 is a schematic representation of further details of FIG. 3.

FIG. 7 is a schematic representation of mechanical and electrical components of the safety device.

FIG. 8 is a schematic representation of electrical components of the safety device.

FIG. 9 is a schematic representation of a method sequence for operating the carrier vehicle shown in FIGS. 1-7.

### DETAILED DESCRIPTION

Reference will now be made in detail to some embodiments of the invention, examples of which are illustrated in the accompanying drawings.

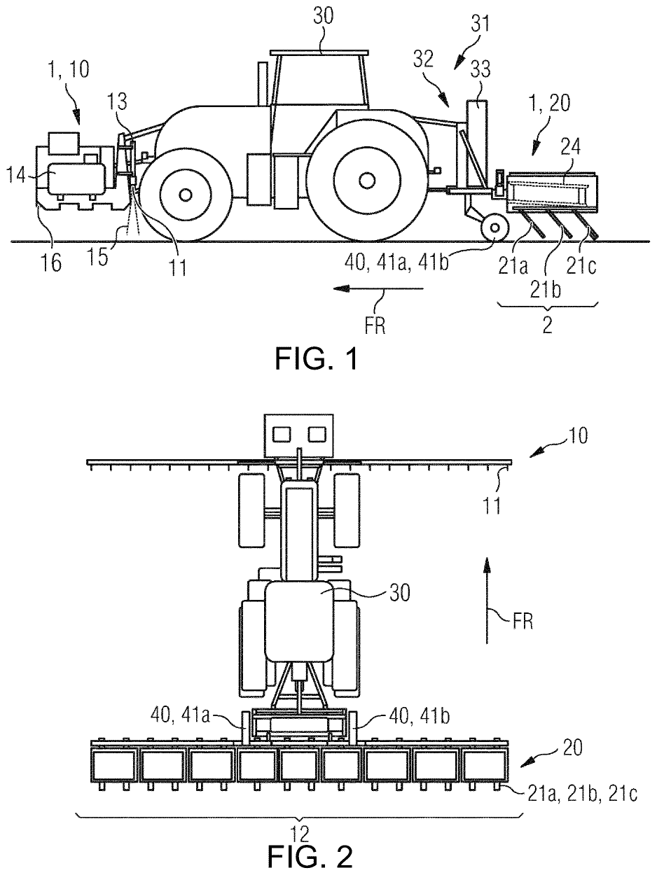

FIG. 1 shows an arrangement of the individual components of a treatment device 1 for treating plants on an agricultural machine serving as a carrier vehicle 30.

By means of the treatment device 1, for example, a desiccation can be brought about by applying electrical current to plants. In this case, provision can be made for electric contact resistances to be reduced by prior application of a contact resistance-reducing medium 15, such as for example a corresponding liquid, before the application of electrical current.

Agricultural machines are specialized machines that are used predominantly in agriculture. They can be configured to be self-propelled or be drawn by an agricultural tractor vehicle, such as a tractor. In other words, the agricultural machine can be a tractor vehicle with its own drive or a trailer without its own drive, which is pulled by a tractor vehicle.

In the present embodiment, the carrier vehicle 30 is designed as a tractor. In deviation from the present embodiment, the carrier vehicle 30 can also be designed as a fertilizer, seed or harvesting machine, which has been modified by attaching the components of the treatment device 1. For this purpose, the components of the treatment device 1 can also be provided in the form of a kit.

The treatment device 1 and the carrier vehicle 30 may vary depending on the mode of use and specific requirements of the crop in question and the time of treatment.

In the present embodiment, the treatment device 1 has a first module 10 for applying the contact resistance-reducing medium 15 and a second module 20 for transmitting direct electrical current to the plants. In deviation from the present embodiment, however, the treatment device 1 can also have only a second module 20 for transmitting electrical current to the plant parts. Furthermore, it can be provided that, for example, in the case of a towing/trailing vehicle combination, consisting of a tractor and a trailer pulled by the tractor, the first module 10 is assigned to the tractor vehicle and components of the second module 20 to the trailer. The components of the second module 20 can also be assigned only to the trailer.

In this embodiment, the contact resistance-reducing medium 15 is a contact resistance-reducing liquid.

In the present embodiment, the first module 10 is arranged on the front side and the second module 20 is arranged on the rear side of the carrier vehicle 30. This arrangement makes it possible for the application of the contact resistance-reducing medium 15 to always take place before or simultaneously with the electrophysical treatment by applying an electrical current, such as direct electrical current.

The first module 10 has at least one application device designed as a nozzle 11. In combination with the nozzle 11, the application device can also comprise a wiper (not shown) or alternatively be itself configured as a wiper. The application device is thus designed for spraying and wiping or applying the contact resistance-reducing medium 15, or alternatively for spraying or wiping. The first module 10 thereby has a number of jointly or preferably individually controllable nozzles 11 or wipers, which are arranged on a first support structure 13 in a desired working width of the treatment device 1 (e.g., 1.5-48 m, preferably 6-27 m) and geometry (statically or flexibly mounted or sensor-controlled in height). The nozzles 11 and/or wipers are supplied with the contact resistance-reducing medium 15, in the present embodiment a liquid, which is stored in one or more liquid containers 14. Sensors 16 are located in the region of the nozzles 11, among others (not shown), the data from which is used to control the application amount of the contact resistance-reducing medium 15 as required. Additional sensors 16 may be located at the front of the first module 10 (i.e., in the direction of travel FR) for the purpose of occupational safety. Sensors used include, but are not limited to, current/voltage sensors, optical sensors such as camera systems, position or movement sensors, LIDAR, metal detectors and others. Drones flying ahead can also be used to detect plants ahead. Furthermore, pasture fence applicators for deterring or startling animals may be disposed on the carrier vehicle 30 or the second module 20.

In the present embodiment, the carrier vehicle 30 provides mechanical drive power via a power-take-off (PTO) shaft 31 or hydraulic circuit to an electric generator 32 of the second module 20, which may be located in the rear region (as shown). The individual modules of the treatment device 1 are arranged as attachments, for example, with three-point suspensions. Special crops require special machines, some of which are already carrier vehicles 30 with special suspensions, if necessary also laterally or under the carrier vehicle 30. In the case of treatment devices 1 with very high power requirements due to, for example, very high working widths or carrier vehicles 30 without sufficient free power capacity, independent power generator systems can also be used, which can be coupled or semi-mounted onto the carrier vehicle 30 or moved on a trailer.

Electrical current is conducted from the generator 32 to electric lines to a transformation and control unit 33 of the second module 20. There, the electrical current is converted for the transformation and then brought to the predetermined electric voltage with a predetermined residual ripple in transformers and other control units positioned centrally or in a distributed manner.

The second module 20 in the present embodiment has a plurality of applicator units 2 each having a plurality of applicators 21a, 21b, 21c for applying direct electrical current to plants. Deviating from the present embodiment, the plants can also be exposed to alternating electrical current.

Additionally, reference is now made to FIG. 2.

The plurality of applicator units 2 are arranged in an applicator row 12, wherein the direction of extension of the applicator row 12 extends transversely, in the present embodiment at an angle of 90°, to the direction of movement FR of the carrier vehicle 30. The applicators 21a, 21b, 21c of the applicator row 12 are arranged on a support structure 24.

In order to reduce the risk of injury, in particular due to electric shocks, during operation of the treatment device 1, a safety device 40 having, in the present embodiment, two grounding disks 41a, 41b is provided.

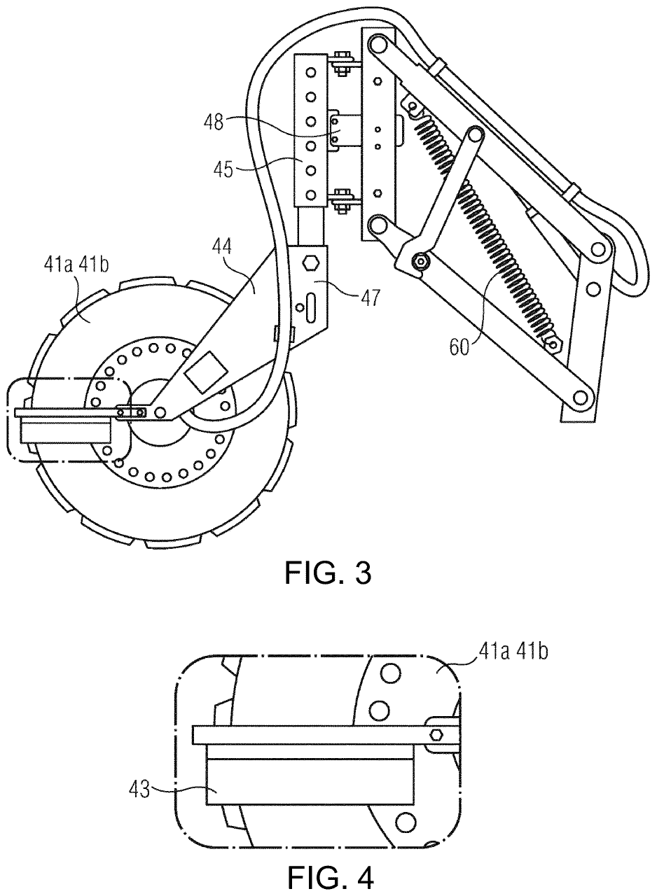

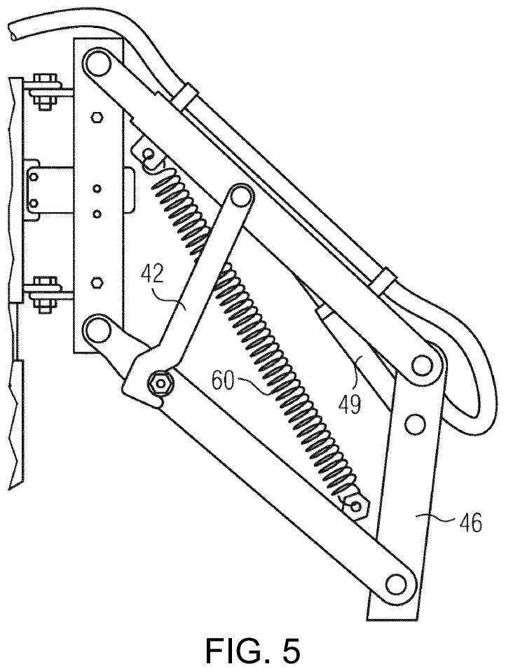

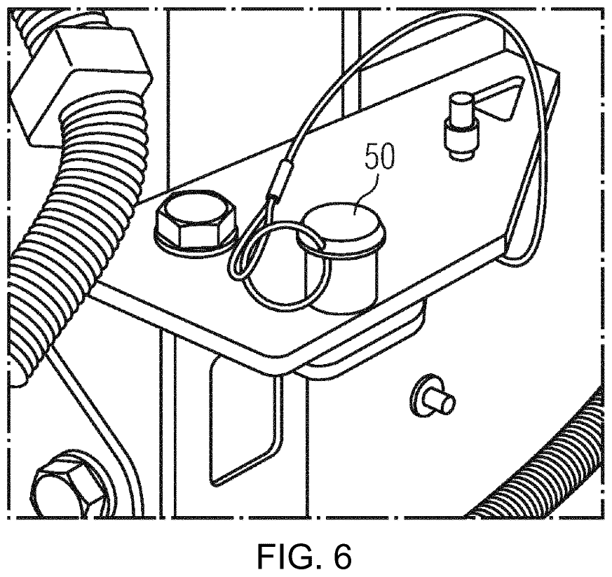

Additionally, reference is now made to FIGS. 3 to 6.

These show mechanical components of the safety device 40 for monitoring the treatment device 1 for treating plants.

In addition to one of the grounding disks 41a, 41b, the mechanical components include a pawl 42, a scraper rubber 43, a handle 44, a height adjustment 45, a swivel arm 46, a swivel adjustment 47, a leaf spring 48, a hydraulic cylinder 49 and a magnetic bolt 50 as well as a tension spring 60.

In the present embodiment, the grounding disks 41a, 41b are a disk-shaped base body made of electrically conductive material, such as stainless steel or aluminum, which is rotatably mounted. Deviating from the present embodiment, the grounding disks 41a, 41b can also have another rotationally symmetrical basic shape, such as that of a cylinder with an outer surface that can roll on the ground.

The pawl 42 is a transport lock for the safety device 40. In the present embodiment, the pawl 42 can be manually engaged and disengaged in order to move in particular the grounding disks 41a, 41b from a transport position into an operating position.

The scraper rubber 43 is provided to remove the biomass and soil that has stuck to the corresponding grounding disks 41a, 41b.

The handle 44 allows the corresponding grounding disk 41a, 41b to be lifted or swiveled.

The height adjustment 45 allows the corresponding grounding disk 41a, 41b to be adjusted to the level of the ground surface. For transport, the grounding disks 41a, 41b can be locked in an upper end position if required. In the present embodiment, the height adjustment 45 is made of an electrically insulating material, such as a plastics material. In the present embodiment, the height adjustment 45 is not electrically bridged in order to allow for a residual current measurement.

In the present embodiment, the swivel arm 46 is configured to be able to swivel the entire assembly by 90° in order to provide access to other components, in particular the treatment device 1.

In addition, in the present embodiment, a track width of the first grounding disk 41a to the second grounding disk 41b can be changed during operation via the swivel arm 46. In the middle position in the present embodiment, the track width is 1.5 m. If the magnetic bolt 50 is moved to the inner position, the grounding disks 41a, 41b can be swiveled outwards so that the track width is increased to 1.95 m, for example.

In the present embodiment, the swivel adjustment 47 allows the corresponding grounding disks 41a, 41b to be swiveled upwards and secured for transport in addition to the height adjustment 45 if required (depending on the size of the carrier vehicle 30).

The leaf spring 48 in the present embodiment ensures that the grounding disk 41a, 41b is aligned along the direction of movement FR or direction of travel during travel.

The hydraulic cylinder 49 is designed to lower and raise the corresponding grounding disk 41a, 41b.

The tension spring 60 pulls “together” the parallelogram guide 57 so that the grounding disk 41a, 41b is always pulled downwards.

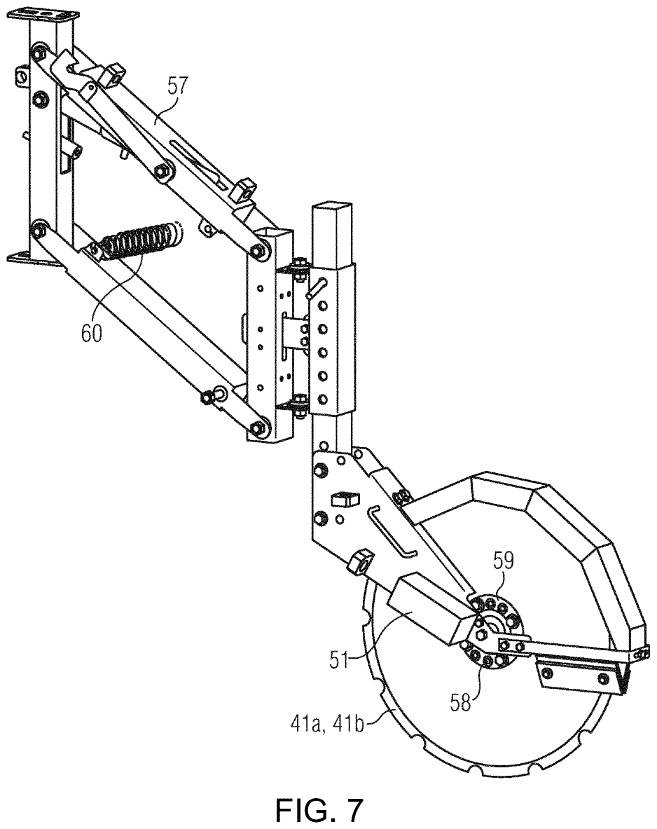

Additionally, reference is now made to FIG. 7.

This shows further mechanical and electrical components of the safety device 40 for monitoring the treatment device 1 for treating plants.

The mechanical components shown are a parallelogram guide 57 for guiding the grounding disk 41a, 41b and fastening nuts 58 for fastening the grounding disk 41a, 41b to a hub.

The electrical components shown are a wheel rotational speed sensor 51 and a trigger wheel 59 which interacts with the wheel rotational speed sensor 51 and which, in the present embodiment, is formed by the fastening nuts 58 arranged in a ring and made of a magnetic material.

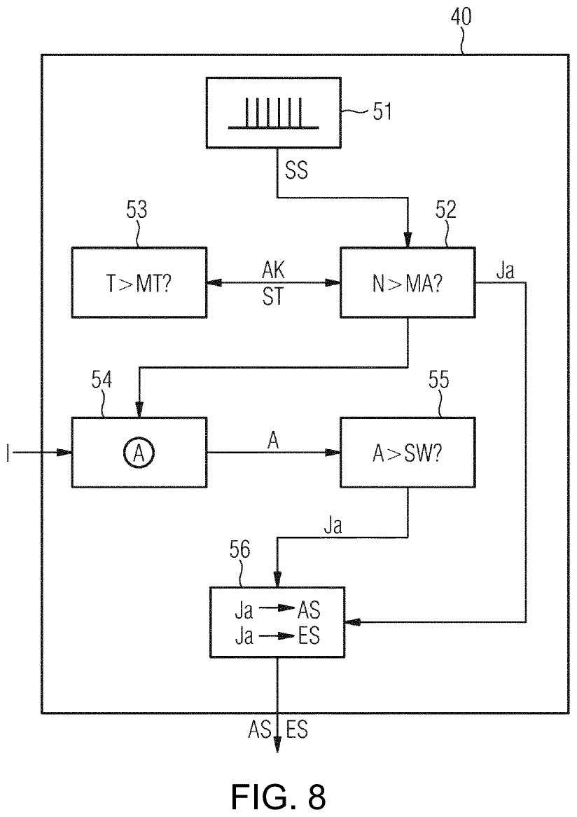

The wheel rotational speed sensor 51 is designed to detect a rotation of the associated grounding disk 41a, 41b and to provide a sensor signal SS (see FIG. 8) that is indicative of a current rotational speed of the grounding disk 41a, 41b, e.g., in the form of pulses per predetermined unit of time. In the present embodiment, the wheel rotational speed sensor 51 is designed as an induction transmitter or sensor. Deviating from the present embodiment, the wheel rotational speed sensor 51 can also be designed as a Hall sensor or as a rotary encoder.

Additionally, reference is now made to FIG. 8.

This shows further electrical components of the safety device 40 for monitoring the treatment device 1 for treating plants.

In addition to the wheel rotational speed sensor 51, the electrical components include an evaluation unit 52, a timer 53, a measuring device 54, a comparator 55 and a control unit 56.

The safety device 40 and the components mentioned can each have hardware and/or software components for their tasks and/or functions described below.

In the present embodiment, the evaluation unit 52 is designed to read the sensor signal SS and, if, for example, a pulse of the sensor signal SS is present, to start the timer 53 by means of an activation signal AK.

The timer 53 then monitors the expiration of a minimum time period MT and sends a stop signal ST to the evaluation unit 52 after the minimum time period MT has elapsed, i.e., when the time period T is greater than the minimum time period MT.

Until the minimum time period MT has elapsed, i.e., until the stop signal ST, the evaluation unit 52 in the present embodiment counts the number N of pulses of the sensor signal ss during the predetermined time interval beginning with the start until the minimum time period MT has elapsed and compares the determined number N with a predetermined minimum number MA of at least two.

If the sensor signal SS has a predetermined minimum number MA of pulses within a predetermined time interval with the minimum time period MT, it is deduced that the sensor signal SS is continuously present. Otherwise, it is assumed that the sensor signal SS is not continuously present.

If the determined number N is greater than the predetermined minimum number MA, the control unit 56 is controlled, which then provides a switch-on signal ES that activates the treatment device 1.

In the present embodiment, the grounding disk 41a and the second grounding disk 41b each provide a sensor signal SS. Before the control unit 56 is controlled, a comparison of the number N of pulses of the two sensor signals SS during the predetermined time interval is performed. The switch-on signal ES is only provided if the deviation between the two values for the number N is smaller than a predetermined error threshold. In other words, an additional error control is achieved by comparing the sensor signals SS provided by the two grounding disks 41a, 41b.

In the present embodiment, the measuring device 54 is designed to detect an electrical current I, i.e., a residual electrical current, which is caused, for example, by an insulation fault of a component of the treatment device 1, and to determine its current strength A.

In the present embodiment, the comparator 55 is designed to compare the current strength A to a predetermined threshold value SW. If the current strength A is greater than the threshold value SW, the control unit 56 is activated, which then provides a switch-off signal AS that deactivates the treatment device 1.

Furthermore, in the present embodiment, it is provided that the treatment device 1 can only be started up by way of the safety device 40 if no electrical current has been detected flowing through the two grounding disks 41a, 41b. This ensures that no treatment device 1 that is already damaged is started up, the start-up of which would otherwise lead to a residual current, e.g., due to an electric insulation of a component of the treatment device 1 that has become damaged in the meantime. In the present embodiment, it is provided that no electrical current is deduced to be flowing through one of the two grounding disks 41a, 41b if a detected electrical current strength A of a detected electrical current is less than a predetermined limit value.

Deviating from the present embodiment, the safety device 40 in particular can also have other mechanical and/or electrical components, and/or the safety device 40 can also be designed without some of the components mentioned.

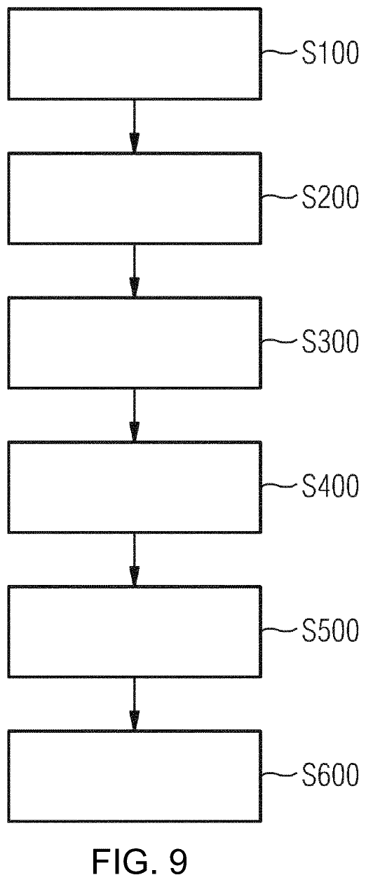

A method sequence for operating the treatment device 1 together with the safety device 40 of the carrier vehicle 30 will now be explained with additional reference to FIG. 9.

In a first step S100, the sensor signal SS indicative of a rotation of the grounding disk 41a, 41b of the safety device 40 is detected in order to deduce that the two grounding disks 41a, 41b are in contact with the ground. The fact that the grounding disk is in contact with the ground ensures reliable detection of a flowing electrical current.

In a further step S200, the treatment device 1 is started up by way of the safety device 40 if a rotation of the grounding disk 41a, 41b and/or no electrical current flowing through one of the two grounding disks 41a, 41b have/has been detected.

For this purpose, it is monitored whether the sensor signal SS indicative of a rotation of the grounding disk 41 has been detected by means of the safety device 40 for a predetermined minimum time period MT. The treatment device 1 is only started up by way of the safety device 40 if the sensor signal SS has been detected continuously throughout the minimum time period MT.

The fact that in the present embodiment, the treatment device 1 can only be started up by way of the safety device 40 if no electrical current flowing through the two grounding disks 41a, 41b has been detected ensures that no treatment device 1 that is already damaged is started up. Their start-up would otherwise result in a residual current, for example due to an electric insulation of a component of the treatment device 1 being damaged in the meantime. In the present embodiment, it is provided that no electrical current is deduced to be flowing through one of the two grounding disks 41a, 41b if a detected electrical current strength A of a detected electrical current is less than a predetermined limit value.

In addition, in the present embodiment, it is provided that the grounding disk 41a and the second grounding disk 41b each provide a sensor signal SS, and a comparison of the number N of pulses of the two sensor signals SS during the predetermined time interval is performed before the control unit 56 is controlled. The switch-on signal ES is provided only if the deviation between the two values for the number N is smaller than a predetermined error threshold.

In a further step S300, an electrical current I flowing through the grounding disk 41a, 41b is detected by means of the safety device 40.

In a further step S400, the electrical current strength A of the detected electrical current I is determined by way of the safety device 40.

In a further step S500, the determined electrical current strength A is compared with the threshold value SW by way of the safety device 40.

In a further step S600, the treatment device 1 is deactivated by the safety device 40 if the determined electrical current strength A of the flowing electrical current I is greater than the threshold value SW.

In deviation from the present embodiment, the sequence of steps may be different. Furthermore, several steps can also be executed simultaneously. Individual steps can also be skipped or omitted in deviation from the present embodiment.

Thus, the safety device 40 can reduce the risk of injury during operation of the carrier vehicle 30 with the treatment device 1 in a particularly simple manner.

### REFERENCE NUMERALS

1 treatment device
2 applicator unit
10 first module
11 nozzle
12 applicator row
13 first support structure
14 liquid container
15 contact resistance-reducing medium
16 sensor
20 second module
21a electric applicator
21b electric applicator
21c electric applicator
24 second support structure
30 carrier vehicle
31 PTO shaft
32 generator
33 transformation and control unit
40 safety device
41a grounding disk
41b grounding disk
42 pawl
43 scraper rubber
44 handle
45 height adjustment
46 swivel arm
47 swivel adjustment
48 leaf spring
49 hydraulic cylinder
50 magnetic bolt
51 wheel rotational speed sensor
52 evaluation unit
53 timer
54 measuring device
55 comparator
56 control unit
57 parallelogram guide
58 fastening nut
59 trigger wheel
60 tension spring
A electrical current strength
AK activation signal
AS switch-off signal
ES switch-on signal
FR direction of movement
I electrical current
SS sensor signal
ST stop signal
SW threshold value
MA minimum number
MT minimum time period
Z number
T time period
S100 step
S200 step
S300 step
S400 step
S500 step
S600 step

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

1-11. (canceled)

12. A method for treating plants, comprising:
detecting a sensor signal output by a wheel rotational speed sensor of a safety device, wherein the sensor signal indicates that a grounding disk is rotating; and
activating a treatment device if either or both the sensor signal is detected or a current sensor detects that no electrical current is flowing through the grounding disk.

13. The method of claim 1, further comprising:
detecting an electrical current flowing through the grounding disk; and
deactivating the treatment device upon detecting the electrical current flowing through the grounding disk.

14. The method of claim 1, wherein the sensor signal indicates that the grounding disk is rotating, wherein the safety device attempts to detect the sensor signal for a predetermined minimum time period, and wherein the safety device starts up the treatment device if the sensor signal is continuously detected throughout the minimum time period.

15. The method of claim 1, further comprising:
determining an electrical current strength of the electrical current detected by the current sensor;
comparing the electrical current strength to a threshold value using a comparator; and
deactivating the treatment device if the electrical current strength of the electrical current is greater than the threshold value.

16. A set of processor-executable instructions stored on a processor-readable medium, wherein execution of the set of processor-executable instructions causes a safety device for monitoring a treatment device for treating plants to perform operations including:
detecting a sensor signal output by a wheel rotational speed sensor of the safety device, wherein the sensor signal indicates that a grounding disk is rotating; and
activating the treatment device if either or both the sensor signal is detected or a current sensor detects that no electrical current is flowing through the grounding disk.

17. The set of processor-executable instructions of claim 16, wherein execution of the set of processor-executable instruction also causes the safety device to perform operations including:
detecting an electrical current flowing through the grounding disk; and
deactivating the treatment device upon detecting the electrical current flowing through the grounding disk.

18. The set of processor-executable instructions of claim 16, wherein execution of the set of processor-executable instruction also causes the safety device to perform operations including:
determining an electrical current strength of the electrical current detected by the current sensor;
comparing the electrical current strength to a threshold value using a comparator; and
deactivating the treatment device if the electrical current strength of the electrical current is greater than the threshold value.

19. A safety device for monitoring a treatment device for treating plants, comprising:
a wheel rotational speed sensor that determines whether a grounding disk is rotating, wherein the treatment device includes the grounding disk; and
a current sensor that detects whether an electrical current is flowing through the grounding disk, wherein the safety device activates the treatment device if either or both the wheel rotational speed sensor determines that the grounding disk is rotating or the current sensor detects that no electrical current is flowing through the grounding disk.

20. The safety device of claim 19, wherein the grounding disk is in contact with the ground when the grounding disk is rotating.

21. The safety device of claim 19, wherein the safety device deactivates the treatment device when the current sensor detects that an electrical current is flowing through the grounding disk.

22. The safety device of claim 19, wherein the wheel rotational speed sensor outputs a sensor signal when the wheel rotational speed sensor determines that the grounding disk is rotating, and wherein the safety device activates the treatment device immediately after the safety device continuously detects the sensor signal throughout a minimum time period.

23. The safety device of claim 19, further comprising:
a comparator, wherein the current sensor detects an electrical current strength of the electrical current, wherein the comparator compares the electrical current strength to a threshold value, and wherein the safety device deactivates the treatment device when the electrical current strength is greater than the threshold value.

24. The safety device of claim 19, wherein the treatment device is mounted on a self-propelled agricultural machine.
